(19) United States
(12) Patent Application Publication
(10) Pub. No.: US 2026/0371503 A1
(43) Pub. Date: Nov. 19, 2026

(54) POWER SUPPLY STRUCTURE

(71) Applicant: Yazaki Corporation, Tokyo (JP)

(72) Inventors: Eri UEDA, Makinohara-shi (JP); Naoto KOGURE, Makinohara-shi (JP); Yasumasa OSADA, Makinohara-shi (JP)

(73) Assignee: Yazaki Corporation, Tokyo (JP)

(21) Appl. No.: 19/644,037

(22) Filed: Apr. 10, 2026

(30) Foreign Application Priority Data
May 15, 2025 (JP) 2025-081624

(51) Int. Cl. H05K 5/02; H01R 35/04

(52) U.S. Cl. CPC H05K 5/0217; H01R 35/04

(57) ABSTRACT

A power supply structure includes a rotating circuit portion connected to a wire harness of a seat and to rotate together with the seat; and a non-rotating circuit portion connected to a power supply and does not rotate even when the seat rotates. The rotating circuit portion includes a plurality of first connectors being at equal distances from a rotating center of the seat. The non-rotating circuit portion includes a single second connector that is able to individually overlap with each of the plurality of the first connectors. The rotating circuit portion and the non-rotating circuit portion are electrically communicated with each other by either of the plurality of the first connectors overlaps with the second connector such that power supply or signal transmission to electrical components of the seat is performed.

### TECHNICAL FIELD

The present invention relates to a power supply structure to a rotatable seat.

### BACKGROUND ART

Conventionally, when electrical components are mounted on a sliding seat of a vehicle, a power supply device is used to supply power to the electrical components from a power source such as a battery (see, for example, Patent Document 1). The power supply device includes an electric wire routed from the power source side to the seat side and an electric wire housing case. The electric wire has a length sufficient to track the sliding of the seat, and an excess length portion is housed in the electric wire housing case.

### CITATION LIST

### Patent Documents

Patent Document 1 JP 2019-50659A

### SUMMARY OF THE INVENTION

### Technical Problem

In recent years, studies have been conducted to make the vehicle seats to be rotatable in addition to be slidable back and forth. However, when conventional power supply devices are used as they are, there was a problem that the durability of the electric wires is reduced because the electric wires are bent or rub against objects near the seat due to the rotating of the seat.

Therefore, an object of the present invention is to provide a power supply structure for a rotatable seat which is superior in durability.

### Solution to Problem

The present invention is a power supply structure to a seat being provided to be rotatable, characterized by including a rotating circuit portion connected to a circuit of the seat and to rotate together with the seat, and a non-rotating circuit portion connected to a power supply and does not rotate even when the seat rotates, wherein the rotating circuit portion includes a plurality of first connectors being at equal distances from a rotating center of the seat, the non-rotating circuit portion includes a single second connector that is able to individually overlap with each of the plurality of the first connectors, and the rotating circuit portion and the non-rotating circuit portion are electrically communicated with each other by either of the plurality of the first connectors overlaps with the second connector.

### Effect of the Invention

According to the present invention, it is possible to provide a power supply structure with superior durability.

### BRIEF DESCRIPTION OF THE DRAWINGS

FIG. 1 is a view showing a power supply structure viewed from above according to an embodiment of the present invention.

FIG. 2 is a view showing the power supply structure in FIG. 1 from a lateral side.

### DESCRIPTION OF EMBODIMENTS

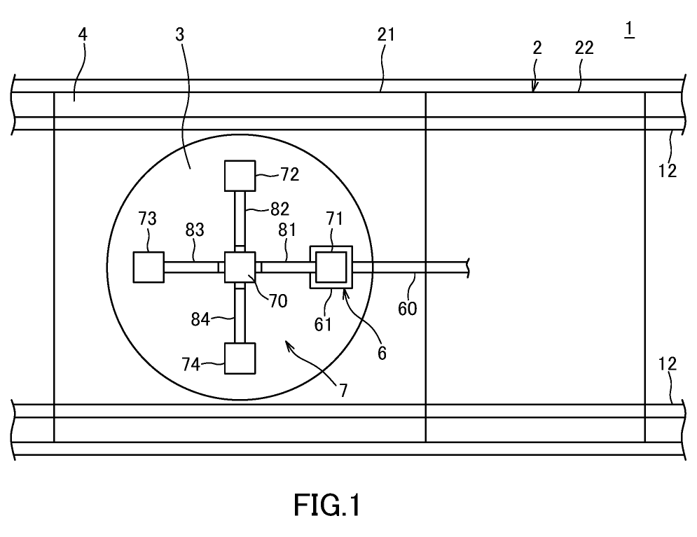

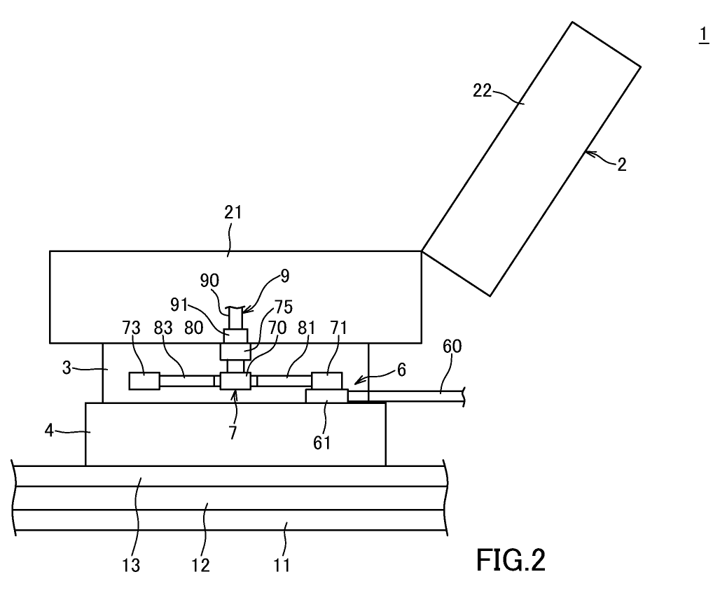

A “power supply structure” according to an embodiment of the present invention will be described by referring to FIGS. 1 and 2.

A power supply structure 1 shown in FIGS. 1 and 2 is the power supply structure 1 to a vehicle seat 2.

The seat 2 has a seating portion 21 and a backrest 22. Electrical components such as a seating sensor, an electric reclining mechanism, and a heater are provided inside the seating portion 21 and the backrest 22. A wire harness 9 for supplying power or transmitting signals to the electrical components is also routed inside the seating portion 21 and the backrest 22. The wire harness 9 has a plurality of electric wires 90 and a plurality of connectors attached to the plurality of electric wires 90 respectively. A connector 91 among the plurality of connectors is connected to a connector 75 of the rotating circuit portion 7, which will be described later, on the bottom surface of the seating portion 21.

A base frame 4 and a rotating mechanism 3 are provided between the bottom portion 21 of the seat 2 and the floor carpet 13. The rotating mechanism 3 is attached to the upper surface of the base frame 4, and the bottom portion 21 is attached to the upper surface of the rotating mechanism 3.

The base frame 4 is slidably supported by a pair of rails 12 attached to a vehicle floor 11. The pair of rails 12 extend in the front-rear direction of the vehicle. Therefore, the base frame 4 is slidable in the front-rear direction.

The rotating mechanism 3 includes a fixing portion fixed to the base frame 4 and a rotating portion fixed to the seating portion 21. The rotating portion together with the seat 2 are rotatable by 360 degrees with respect to the fixing portion and the base frame 4. A bearing may be interposed between the fixing portion and the rotating portion.

In this manner the seat 2 is provided so as to be slidable in the front-rear direction and rotatable by 360 degrees. Then, in the present example, the seat 2 is rotated manually rather than electrically.

The power supply structure 1 includes a rotating circuit portion 7 that is connected to a wire harness 9 of the seat 2 and rotates together with the seat 2, and a non-rotating circuit portion 6 that is connected to a power source such as a battery or the like and does not rotate even when the seat 2 rotates. According to the present example, the non-rotating circuit portion 6 is indirectly connected to the power supply source via an electronic control portion, however, it may also be directly connected to the power supply source.

The non-rotating circuit portion 6 includes an electric wire 60 with sufficient length to track the sliding of the seat 2 in the front-rear direction, and a connector 61 attached to one end of the electric wire 60. Hereinafter, the connector 61 will be referred to as the second connector 61. One end of the electric wire 60 is drawn into the inner space of the rotating mechanism 3 and fixed to a fixing portion of the rotating mechanism 3. The second connector 61 includes a plurality of contacts and a housing that retains these contacts. The other end of the electric wire 60 is connected to the electronic control portion. The excess length portion of the electric wire 60 is housed in an electric wire housing case (not shown) attached to the vehicle floor 11.

The rotating circuit portion 7 includes four connectors 71, 72, 73, 74, one joint connector 70, one connector 75, and electric wires 80, 81, 82, 83, 84 connecting these connectors. Hereinafter, the connectors 71, 72, 73, 74 will be referred to as first connectors 71, 72, 73, 74, respectively. The rotating circuit portion 7 is disposed in the inner space of the rotating mechanism 3 and attached to the rotating portion of the rotating mechanism 3.

The four first connectors 71, 72, 73, 74 are arranged at equal distances and at equal intervals from the rotation center of the seat 2. These four first connectors 71, 72, 73, 74 have the same configuration and each includes a plurality of spring contacts and a housing that retains these contacts.

The joint connector 70 is disposed at the rotation center of the seat 2. The electric wire 81 connects the first connector 71 and the joint connector 70. The electric wire 82 connects the first connector 72 and the joint connector 70. The electric wire 83 connects the first connector 73 and the joint connector 70. The electric wire 84 connects the first connector 74 and the joint connector 70.

The connector 75 is connected to a connector 91 of the wire harness 9 of the seat 2. An electric wire 80 connects the connector 75 to the joint connector 70. The connector 75 is connected to all of the first connectors 71, 72, 73, 74 via the joint connector 70 and the electric wires 80, 81, 82, 83, 84.

As the seat 2 rotates, the second connector 61 of the non-rotating circuit portion 6 can individually overlap the plurality of first connectors 71, 72, 73, 74, respectively. In the example shown in FIGS. 1 and 2, the seat 2 is facing forward of the vehicle, and the first connector 71 overlaps the second connector 61. In this state, the plurality of contacts of the first connector 71 with springiness are in elastic contact with the plurality of contacts of the second connector 61, respectively. When the seat 2 is rotated by 90 degrees clockwise from this state, the first connector 72 overlaps the second connector 61. When rotated by another 90 degrees, the first connector 73 overlaps the second connector 61, and when rotated by further another 90 degrees, the first connector 74 overlaps the second connector 61.

In this way, when any of the four first connectors 71, 72, 73, 74 overlaps with the second connector 61, the rotating circuit portion 7 and the non-rotating circuit portion 6 are electrically connected, and the power supply or the signal transmission are performed with respect to the electrical components of the seat 2. When the four first connectors 71, 72, 73, 74 do not overlap with the second connector 61, the rotating circuit portion 7 and the non-rotating circuit portion 6 are not electrically connected.

According to the power supply structure 1 configured as described above, the electric wires 60, 80, 81, 82, 83, 84 are not bent or twisted due to the rotating of the sheet 2, and the electric wires 60, 80, 81, 82, 83, 84 do not rub against objects near the sheet 2. Therefore, the power supply structure 1 can be made to have superior durability.

According to the above-described embodiment, the rotating circuit portion 7 and the non-rotating circuit portion 6 are electrically connected every time the seat 2 is rotated by 90 degrees, but according to the present invention, by increasing the number of first connectors, it is possible to electrically connect the rotating circuit portion 7 and the non-rotating circuit portion 6 every angle smaller than 90 degrees. The number of first connectors may be two or more and can be set freely.

According to the above-described embodiment, the seat 2 can be rotated by 360 degrees, however, the angle at which the seat 2 can be rotated can be set freely.

According to the above-described embodiment, the seat 2 is configured to be rotated manually, however, the seat 2 can also be configured to be rotated electrically. In a case of making it to operate electrically, an electric rotation mechanism and a battery can be mounted in the seat 2. In this way, even if the rotating circuit portion 7 and the non-rotating circuit portion 6 are not electrically connected, the electric rotating mechanism can be driven to rotate the seat 2.

The above-described embodiment merely shows a typical form of the present invention, and the present invention is not limited to this embodiment. In other words, the present invention can be implemented with various modifications within the scope of the gist of the present invention. As long as such modifications still include the configuration of the present invention, they are of course included in the scope of the present invention.

### REFERENCE SIGNS LIST

1 power supply structure
2 seat
3 rotating mechanism
4 base frame
6 non-rotating circuit portion
7 rotating circuit portion
61 second connector
70 joint connector
71, 72, 73, 74 first connector

What is claimed is:

1. A power supply structure to a seat being provided to be rotatable, comprising
a rotating circuit portion connected to a circuit of the seat and to rotate together with the seat; and
a non-rotating circuit portion connected to a power supply and does not rotate even when the seat rotates,
wherein the rotating circuit portion includes a plurality of first connectors being at equal distances from a rotating center of the seat,
the non-rotating circuit portion includes a single second connector that is able to individually overlap with each of the plurality of the first connectors, and
the rotating circuit portion and the non-rotating circuit portion are electrically communicated with each other by either of the plurality of the first connectors overlaps with the second connector.

2. The power supply structure according to claim 1, wherein the rotating circuit portion includes a single joint connector that is connected to the plurality of first connectors via an electric wire.

3. The power supply structure according to claim 1,
wherein the seat is rotatably supported by a rotating mechanism on a base frame that is slidably provided, and
the rotating circuit portion is attached to the rotating mechanism.
